(19) United States
(12) Patent Application Publication
(10) Pub. No.: US 2026/0173836 A1
(43) Pub. Date: Jun. 18, 2026

(54) METHOD OF REMOVING RESIDUE FROM AN ELECTRONIC COMPONENT AND FABRICATION OF AN ELECTRONIC DEVICE INCLUDING THE ELECTRONIC COMPONENT

(71) Applicant: LINCO TECHNOLOGY CO., LTD., Taichung City (TW)

(72) Inventors: Cheng-Yu TSAO, Taichung City (TW); Yi-Yuan HUANG, Taichung City (TW); Guan-Ru LIU, Taichung City (TW)

(21) Appl. No.: 19/419,831

(22) Filed: Dec. 15, 2025

(30) Foreign Application Priority Data
Dec. 18, 2024 (TW) 113149397

(51) Int. Cl. H10W 20/00; H05K 3/00

(52) U.S. Cl. CPC H10W 20/082; H05K 3/0026; H05K 3/0041; H05K 2203/095; H10W 20/056

(57) ABSTRACT

A method of fabricating an electronic device includes: forming an insulating layer on a metallic layer of an electronic component; laser drilling the insulating layer to form via holes; performing a plasma hard-etching to remove metal oxide residue inside the via holes; performing a plasma soft-etching to remove oxide residue inside the via holes; covering the insulating layer and via holes; with a patterned seed crystal layer; covering the patterned seed crystal layer to obtain the electronic component. A method of removing residue from the electronic component includes: performing a plasma hard-etching to remove metal oxide residue inside the via holes, followed by performing a plasma soft-etching to remove oxide residue inside the via holes.

### CROSS-REFERENCE TO RELATED APPLICATION

This application claims priority to Taiwanese Invention patent application No. 113149397, filed on Dec. 18, 2024, the entire disclosure of which is incorporated by reference herein.

### FIELD

The disclosure relates to a method of fabricating an electronic device, and more particularly to a method of removing residue from an electronic component and a method of fabricating an electronic device including the electronic component.

### BACKGROUND

A redistribution (RDL) layer is conventionally known as a layer of wiring on an IC chip that changes the location from which the IC chip may be bonded. The IC chip may be formed with the RDL layer for adaptation to different IC packaging processes or multi-chip packaging processes.

During the processing of the RDL layer laser drilling is conducted on a dielectric layer to form via holes interconnecting different circuit layers. However, the laser drilling causes residue to remain in the via holes, and a plasma etching process is performed to remove the residue.

However, conventional plasma etching processes currently available often are conducted at high power, and the via holes are bombarded without intermission. This may cause erosion of metal pads on the IC chip, and cause heat damage or create fissures on the IC chip that are detrimental to the functioning of the IC chip which lowers yield rates.

### SUMMARY

Therefore, an object of the disclosure is to provide a method of fabricating an electronic device and a method of removing residue from an electronic component included in the electronic device, that can alleviate at least one of the drawbacks of the prior art.

According to one aspect of the disclosure, the method of an electronic device includes: A) forming an insulating layer on a metallic patterned layer of an electronic component which is to be processed to form the electronic device; B) laser drilling the insulating layer to form a plurality of via holes; C) performing a plasma hard-etching at the via holes at a higher etch rate of no less than 100 Å/min to remove metal oxide residue formed inside the via holes after the laser drilling, the plasma hard-etching at the higher etch rate is conducted using inductively coupled plasma reactive-ion etching (ICP RIE), reactive-ion etching (RIE), or an ion source; D) performing a plasma soft-etching at the via holes at a lower etch rate of less than 100 Å to remove oxide residue generated inside the via holes after the plasma hard etching at the higher etch rate, the plasma soft-etching is conducted using a power that is lower than that used for the plasma hart-etching, the plasma soft-etching is conducted using ICP RIE, RIE, or IBE; e) after the plasma soft-etching, covering the insulating layer and the via holes with a patterned seed crystal layer; and F) covering the patterned seed crystal layer with a metallic conductor layer to obtain the electronic component.

According to another aspect of the disclosure, a method of removing residue from an electronic component is provided. The electronic component includes a metallic patterned layer and an insulating layer that cover the metallic patterned layer and has a plurality of via holes. The method includes the steps of: performing a plasma hard-etching at the via holes at a higher etch rate of no less than 100 Å to remove metal oxide residue formed on the metallic patterned layer inside the via holes, the plasma hard-etching at the higher etch rate is conducted using inductively coupled plasma reactive-ion etching (ICP RIE), reactive-ion etching (RIE), or an ion source; and performing a plasma soft-etching at the via holes at a lower etch rate of less than 100 Å to remove oxide residue generated inside the via holes after the plasma hard-etching at the higher etch rate, the plasma soft-etching is conducted using a power that is lower than that used for the plasma hard-etching at the via holes. The plasma soft-etching is conducted using ICP RIE, RIE, or IBE.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a method of fabricating an electronic device according to the present disclosure.

FIGS. 2 to 7 are fragmentary schematic cross-sectional views illustrating processing steps in the method according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

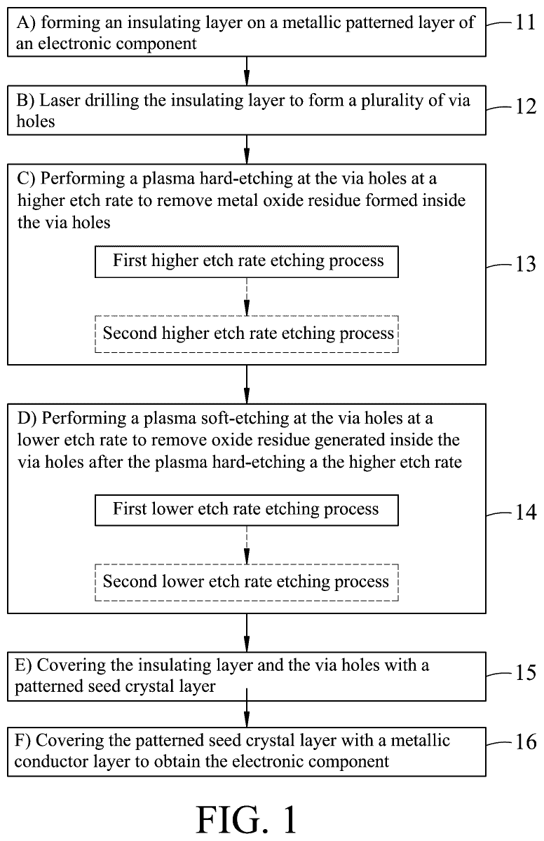

Referring to FIG. 1, a method of fabricating an electronic device includes the steps A) to F). The method is adapted for processing an electronic component 2 for forming a redistribution layer (RDL) on the electronic component 2. However, in other embodiments, the electronic component 2 may be processed to form other structures or layers.

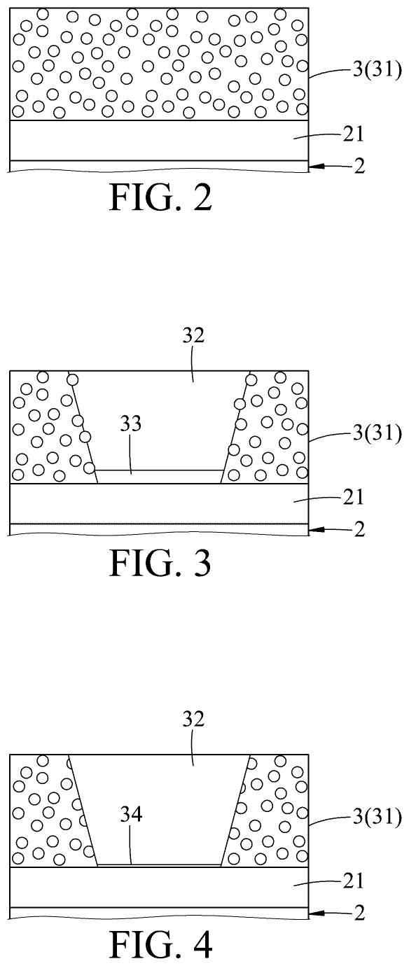

Referring to FIG. 2, in the step A) an insulating cover 3 having an insulating layer 31 is formed on a metallic patterned layer 21 of the electronic component 2. In this embodiment, the electronic component 2 is a die that has been processed via a semiconductor fabrication process and then cut and transferred unto a rectangular substrate. The metallic patterned layer 21 is a collection of metal pads on the electronic component 2 (which is a chip in this embodiment) that enables the electronic component 2 to connect a wiring circuit; the metal pads may be aluminum pads or copper pads. In some embodiments, the electronic component 2 is an IC substrate, or a printed circuit board (PCB), and the metallic patterned layer 21 may be made of titanium, aluminum, copper, nickel, gold or a combination thereof. The insulating cover 3 may be an Ajinomoto build-up Film® (ABF) that mainly includes epoxy, and an inorganic filler which may be, but is not limited to, silicon dioxide (SiO₂) filler particles. In some embodiments, the insulating cover 3 may be another material, such as an epoxy molding compound (EMC), other than the Ajinomoto build-up Film® (ABF).

Referring to FIG. 3, in the step B) the insulating layer 31 is laser drilled to form a plurality of via holes 32. It should be noted that in the step B) the insulating layer 31 is laser drilled to expose the metallic patterned layer 21 from the bottom of the via holes 32. However, the exposed metallic patterned layer 21 will form metal oxide residue 33 such as aluminum oxide (Al₂O₃) at the bottom of the via holes 32 upon exposure to the external atmosphere. The metal oxide residue 33 thus formed usually has a thickness that ranges from 15 nm to 30 nm.

Referring to FIG. 4, in the step C), plasma hard-etching is performed at the via holes 32 at a higher etch rate of no less than 100 Å/min to remove the metal oxide residue 33 formed on the metallic patterned layer 21 inside the via holes 32 after the laser drilling. It should be noted that when the hard-etching is performed, the side walls of the via holes 32 are also etched in order to remove as much of on the silicon oxide filler particles of the insulating layer 31 protruding from the side walls of the via holes 32, and the voids left by the filler particles may be filled by other constituents of the insulating cover 3. This will ensure that the side walls of the via holes 32 are even and clean after performing the plasma hard-etching. In this embodiment, in the step C), the plasma hard-etching is conducted at a higher etch rate that is no less than 150 Å/min. The plasma hard-etching at the higher etch rate may be conducted using inductively coupled plasma reactive-ion etching (ICP RIE), reactive-ion etching (RIE), or an ion source.

In some embodiments, when the plasma hard-etching at the higher etch rate is conducted using ICP RIE, the plasma hard-etching is conducted at a vacuum pressure ranging from 0.5 mTorr to 5 mTorr. The plasma hard-etching may be conducted in a vacuum chamber (not shown) filled with argon (Ar) gas, helium (He) gas, or hydrogen (H₂) gas. In a test experiment, the plasma hard-etching was conducted with the below settings, where the vacuum chamber was filled with argon gas, the vacuum pressure was set at 1 mTorr, a source electrode had a power of 2 kw, and a bias power was 2.7 kw. With these settings, the plasma hard-etching had an etch rate of 197 Å/min, a source electrode power density of 0.468 w/cm², and a bias electrode power density of 0.632 w/cm². It should be noted that the etch rate mentioned above refers to an etch rate obtained from plasma hard-etching a standard test piece. More specifically, the test piece is a glass substrate board adhered with a plurality of silicon wafers having silicon oxide (SiO₂) on the wafer surfaces thereof. The test piece is partially covered with a polyimide thin film to form a covered region and an etching region. The etch rate is obtained by measuring a difference in thickness of the silicon oxide between the covered region and the etching region after performing the plasma hard-etching, and dividing the difference in thickness by the etching time.

In some embodiments, the plasma hard-etching may be performed intermittently for improved temperature control. In some embodiments, during the step of plasma hard-etching at the higher etch rate, a gas such as argon (Ar) gas or helium (He) gas may be blown onto the electronic component 2. In some embodiments, vacuuming of the vacuum chamber may be temporarily stopped to blow argon (Ar) gas or helium (He) gas onto the electronic component part 2, and then resuming the vacuuming and conducting the plasma hard-etching. This may help facilitate the swift removal of byproducts such as CO that are generated by the plasma hard-etching, and may help reduce the formation of new substances during the etching process.

In some embodiments, the plasma hard-etching may be conducted in multiple stages to ensure better etching results are achieved. For example, the step of plasma hard-etching at the higher etch rate may include a first higher etch rate etching process that uses a first higher etch rate, and a second higher etch rate etching process that uses a second higher etch rate, and the first higher etch rate is different from the second higher etch rate. In some embodiments, the plasma hard-etching may include a third higher etch rate etching process, a fourth higher etch rate etching process, or even more etching processes according to practical requirements.

In addition to etching to remove the metal oxide residue 33, the plasma hard-etching can also induce generation of a coating in the electronic component 2. This is because when the metal oxide residue 33 is being etched, some of it may be re-sputtered as oxygen radicals or oxygen molecules which may re-combine with ionized silicon molecules from the insulating cover 3 or metal particles from the metal oxide residue 33 to form an oxide residue 34 such as silicon oxide SiOₓ or aluminum oxide AlₓO_{y}. Therefore, during the plasma hard-etching process, even as the metal oxide residue 33 is etched away, a new oxide residue 34 is gradually generated. However, it should be noted that under normal circumstances, the oxide residue 34 newly generated after performing the plasma hard-etching at a higher etch rate has a thickness that is less than 10 μm.

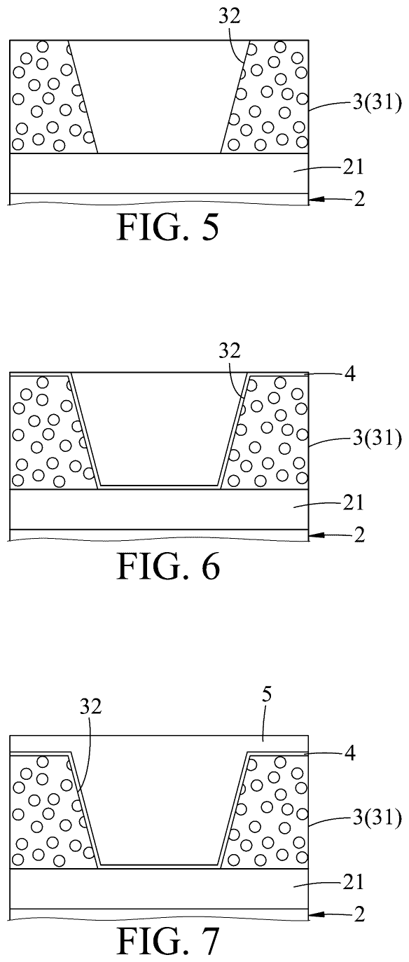

Referring to FIGS. 4 and 5, in the step D) a plasma soft-etching at the via holes 32 at a lower etch rate of less than 100 Å is performed to remove oxide residue 34 generated inside the via holes 32 after the plasma hard-etching at the higher etch rate. The oxide residue 34 that is removed in the step of plasma soft-etching may be silicon oxide or aluminum oxide. The plasma soft-etching is conducted using a power that is lower than that used for the plasma hard-etching. For example, a bias power used in the step of plasma hard-etching at the higher etch rate may be greater than that used in the plasma soft-etching at the lower etch rate. More generally, the plasma soft-etching is conducted with lower power, lower plasma density, and a lower etch rate to remove oxide residue 34. The plasma soft-etching may be conducted using ICP RIE, RIE, or IBE.

In some embodiments, when the plasma soft-etching is conducted using ICP RIE, the plasma soft-etching at the lower etch rate is conducted at a vacuum pressure ranging from 5 mTorr to 10 mTorr. A vacuum chamber (not shown) used to conduct the plasma soft-etching may be filled with argon (Ar) gas, helium (He) gas, or hydrogen (H₂) gas. It should be noted that, in some embodiments, the step of plasma hard-etching at the higher etch rate and the step of plasma soft-etching at the lower etch rate are respectively conducted in the same vacuum chamber. However, in other embodiments, the step of plasma hard-etching at the higher etch rate and the step of plasma soft-etching at the lower etch rate may be respectively conducted in two different vacuum chambers. An operator may decide whether to conduct the plasma hard-etching and the plasma soft-etching in the same vacuum chamber or in different vacuum chambers according to production requirements. In an experiment that was conducted for performing the plasma soft-etching, an argon (Ar) gas is filled in the vacuum chamber for conducting the plasma soft-etching, the source power is set at 1 kw, the bias power is set to be in a range from 0.5 kw to 2 kw. Furthermore, the experiment had settings where the source electrode power density ranges from 0.1 w/cm² to 0.3 w/cm², and the bias electrode power density ranges from 0.2 w/cm² to 0.6 w/cm². With the above settings, the plasma soft-etching was able to achieve an etch rate that ranges from 30 Å/min to 70 Å/min.

In some embodiments, the plasma soft-etching may be performed intermittently to achieve better temperature control. In some other embodiments, during the step of plasma soft-etching at the lower etch rate, a gas such as argon (Ar) gas or helium (He) gas may be blown onto the electronic component 2. In some embodiments, vacuuming of the vacuum chamber may be temporarily stopped to blow argon (Ar) gas or helium (He) gas onto the electronic component 2, and then resuming the vacuuming and conducting the plasma hard-etching. This may help facilitate the swift removal of byproducts that may be generated by the plasma soft-etching, and may help reduce the formation of new substances during the etching process.

In some embodiments, the plasma soft-etching may be performed in multiple stages to ensure that better soft-etching results may be achieved. For example, in this embodiment, the step of plasma soft-etching at the lower etch rate includes a first lower etch rate etching process that uses a first lower etch rate, and a second lower etch rate etching process that uses a second lower etch rate, and the first lower etch rate is different from the second lower etch rate. In some embodiments, the plasma soft-etching may include a third lower etch rate etching process, a fourth lower etch rate etching process, or even more etching processes according to practical requirements. In this embodiment, the first lower etch rate etching process and the second lower etch rate etching process are respectively conducted in two different vacuum chambers; however, this disclosure is not thus limited, and in other embodiments, the first lower etch rate etching process and the second lower etch rate etching process may be conducted in the same vacuum chamber.

In some embodiments, when the plasma soft-etching is conducted using RIE, the plasma soft-etching at the lower etch rate is conducted with a bias electrode power ranging from 1 kw to 2.7 kw. When the plasma soft-etching in the step D) is conducted using IBE with a power ranging from 2 KV to 5 KV, the vacuum pressure ranges from 0.5 mTorr to 3 mTorr.

Referring to FIG. 7, in the step E) after performing the plasma soft-etching, the insulating layer 31 and the via holes 32 are covered with a patterned seed crystal layer 4. The seed crystal layer 4 is formed via sequential sputtering or deposition of titanium and copper layers.

Referring to FIG. 7, in the step F) the patterned seed crystal layer 4 is covered with a metallic conductor layer 5 to obtain the electronic device. The metallic conductor layer 5 may be made of a metal such as copper, and formed via electro plating or deposition. The metallic conductor layer 5 may be patterned via a photolithography process, and is filled into the via holes 32 to electrically connect the metallic patterned layer 21. In this embodiment, after performing the steps A) to F) a single RDL layer is obtained, however, the steps A) to F) may be performed repeatedly to obtain a multilayered RDL.

In the method of fabricating an electronic device according to the present disclosure, multi-staged plasma etching is performed via the plasma hard-etching and the plasma soft-etching. The multi-staged plasma etching allows effective removal of residue from the via holes 32 to ensure the via holes 32 are clean. This prevents over etching, heat damage or the development of fissures in the metallic patterned layer 21, and decreases the amount of contact resistance (Rc) between the metallic conductor layer 5 and the metallic patterned layer 21 which improves electric conductivity, improves performance characteristics, and yield rates.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method of removing residue from an electronic component using plasma etching during fabrication of an electronic device, the electronic component including a metallic patterned layer and an insulating layer that covers the metallic patterned layer, and that has a plurality of via holes, the method comprising the steps of:
a) performing a plasma hard-etching at the via holes at a higher etch rate of no less than 100 Å to remove metal oxide residue formed from the metallic patterned layer inside the via holes, the plasma hard-etching at the higher etch rate being conducted using inductively coupled plasma reactive-ion etching (ICP RIE), reactive-ion etching (RIE), or an ion source; and
b) performing a plasma soft-etching at the via holes at a lower etch rate of less than 100 Å to remove oxide residue generated inside the via holes after the plasma hard-etching at the higher etch rate, the plasma soft-etching being conducted using a power that is lower than that used for the plasma hard-etching at the via holes, the plasma soft-etching is conducted using ICP RIE, RIE, or IBE.

2. The method as claimed in claim 1, wherein during the step of plasma hard-etching at the higher etch rate, or the step of soft-etching the via holes at the lower etch rate, a gas is intermittently blown onto the electronic component.

3. The method o as claimed in claim 1, wherein the step of plasma hard-etching at the higher etch rate and the step of soft-etching at the lower etch rate are conducted in a same vacuum chamber.

4. The method as claimed in claim 1, wherein the step of plasma hard-etching at the higher etch rate and the step of plasma soft-etching at the lower etch rate are respectively conducted in two different vacuum chambers.

5. The method as claimed in claim 1, wherein:
the step of plasma hard-etching at the higher etch rate includes a first higher etch rate etching process that uses a first higher etch rate, and a second higher etch rate etching process that uses a second higher etch rate; and
the first higher etch rate is different from the second higher etch rate.

6. The method as claimed in claim 1, wherein:
the step of plasma soft-etching at the lower etch rate includes a first lower etch rate etching process that uses a first lower etch rate, and a second lower etch rate etching process that uses a second lower etch rate; and
the first lower etch rate is different from the second lower etch rate.

7. The method as claimed in claim 6, wherein:
the first lower etch rate etching process and the second lower etch rate etching process are respectively conducted in two different vacuum chambers.

8. The method as claimed in claim 1, wherein:
in the step of plasma hard-etching at the higher etch rate, a source electrode power density is 0.468 w/cm²; and
in the step of plasma soft-etching at the lower etch rate, a source electrode power density ranges from 0.1 w/cm² to 0.3 w/cm².

9. The method as claimed in claim 1, wherein:
the step of plasma hard-etching at the higher etch rate is conducted at a vacuum pressure ranging from 0.5 mTorr to 5 mTorr; and
the step of plasma soft-etching at the lower etch rate is conducted at a vacuum pressure ranging from 5 mTorr to 10 mTorr.

10. The method as claimed in claim 1, wherein a bias power used in the step of plasma hard-etching at the higher etch rate is greater than that used in the plasma soft-etching at the lower etch rate.

11. The method as claimed in claim 1, wherein the oxide residue generated after in performing the plasma hard-etching at a higher etch rate has a thickness that is less than 10 μm.

12. The method as claimed in claim 1, wherein:
the step of plasma hard-etching is conducted at a higher etch rate that is no less than 150 Å/min; and
the step of plasma soft-etching is conducted at a lower etch rate that ranges from 30 Å/min to 70 Å/min.

13. The method as claimed in claim 1, wherein:
the metal oxide residue that is removed in the step of plasma hard-etching is aluminum oxide; and
the oxide residue that is removed in the step of plasma soft-etching is silicon oxide, or aluminum oxide.

14. A method of fabricating an electronic device comprising:
A) forming an insulating layer on a metallic patterned layer of an electronic component;
B) laser drilling the insulating layer to form a plurality of via holes;
C) performing a plasma hard-etching at the via holes at a higher etch rate of no less than 100 Å/min to remove metal oxide residue formed inside the via holes after the laser drilling, the plasma hard-etching at the higher etch rate being conducted using inductively coupled plasma reactive-ion etching (ICP RIE), reactive-ion etching (RIE), or an ion source;
D) performing a plasma soft-etching at the via holes at a lower etch rate of less than 100 Å to remove oxide residue generated inside the via holes after the plasma hard-etching at the higher etch rate, the plasma soft-etching being conducted using a power that is lower than the that used for the plasma hard-etching, the plasma soft-etching being conducted using ICP RIE, RIE, or IBE;
E) after performing the plasma soft-etching, covering the insulating layer and the via holes with a patterned seed crystal layer; and
F) covering the patterned seed crystal layer with a metallic conductor layer to obtain the electronic component.

15. The method as claimed in claim 14, wherein the electronic component is a chip, an IC substrate, or a printed circuit board (PCB).

16. The method as claimed in claim 14, wherein the metallic patterned layer is made of titanium, aluminum, copper, nickel, gold, or a combination thereof.
